(19) United States
(12) Patent Application Publication
(10) Pub. No.: US 2026/0066034 A1
(43) Pub. Date: Mar. 5, 2026

(54) REPAIR STRUCTURE FOR EXTREME-BANDWIDTH THREE-DIMENSIONAL (3D) STACKED DYNAMIC RANDOM-ACCESS MEMORY (DRAM) INCLUDING BASE DIE FOR NEAR-MEMORY COMPUTING

(71) Applicant: QUALCOMM Incorporated, San Diego, CA (US)

(72) Inventors: Mustafa BADAROGLU, San Diego, CA (US); Zhongze WANG, San Diego, CA (US); Woo Tag KANG, San Diego, CA (US); Jihong CHOI, San Diego, CA (US); Giridhar NALLAPATI, San Diego, CA (US); Periannan CHIDAMBARAM, San Diego, CA (US)

(21) Appl. No.: 19/313,118

(22) Filed: Aug. 28, 2025

Related U.S. Application Data
(60) Provisional application No. 63/689,388, filed on Aug. 30, 2024.

(51) Int. Cl. G11C 29/00; G11C 29/12; G11C 29/44

(52) U.S. Cl. CPC G11C 29/702; G11C 29/1201; G11C 29/44

(57) ABSTRACT

A three-dimensional (3D) stacked memory package is described. The 3D stacked memory package includes a base die having an array of processing units (PUs) including at least one spare PU. The 3D stacked memory package also includes memory dies stacked on the base die and having bank tiles, including at least one spare bank tile. The 3D stacked memory package further includes a package substrate supporting the base die. The 3D stacked memory package also includes through substrate vias (TSVs) extending between the memory dies and landing on the base die and having at least one spare TSV per bank tile. The 3D stacked memory package further includes a repair structure configured to reroute a data/control bus to replace one of a failed bank tile with the spare bank tile, a failed TSV with the at least one spare TSV, and/or a failed PU with the spare PU.

### CROSS-REFERENCE TO RELATED APPLICATION

The present Application for Patent claims the benefit of U.S. Provisional Ser. No. 63/689,388 entitled “REPAIR STRUCTURE FOR EXTREME-BANDWIDTH THREE-DIMENSIONAL (3D) STACKED DYNAMIC RANDOM-ACCESS MEMORY (DRAM) INCLUDING BASE DIE FOR NEAR-MEMORY COMPUTING,” filed Aug. 30, 2024, assigned to the assignee hereof, and expressly incorporated herein by reference in its entirety.

### BACKGROUND OF THE DISCLOSURE

### 1. Field of the Disclosure

Aspects of the present disclosure relate to semiconductor devices and, more particularly, to a repair structure for extreme-bandwidth three-dimensional (3D) stacked dynamic random-access memory (DRAM) including a base die for near-memory computing.

### 2. Description of the Related Art

Memory is a vital component for wireless communications devices. For example, a cell phone may integrate memory as part of an application processor, such as a system-on-chip (SoC) including a central processing unit (CPU), a graphics processing unit (GPU), and a neural processing unit (NPU). Successful operation of some applications depends on the availability of a high-capacity and low-latency memory solution for scalability of processor workload. A semiconductor memory device solution for providing a high-capacity, low-latency, and high-bandwidth memory is an existing goal for system designers.

Semiconductor memory devices include, for example, static random-access memory (SRAM) and dynamic random-access memory (DRAM). State of the art three-dimensional (3D) stacked memories composed of high-bandwidth memory (HBM) DRAM provide advantages in performance and power for memory-demanding workloads. Single stacked DRAM yield is a significant factor in these 3D stacked memories. For example, a single DRAM yield of 90% is reduced to a stacked yield of less than 43% in an integration scheme that utilizes low-cost wafer-to-wafer stacking of eight wafers. Combined with an additional die yield of 80%, overall stacked yield drops to 34%. Due to this limited yield, DRAM vendors prefer slow and costly die-to-die stacking for implementing high-bandwidth memory (HBM) solutions. Additionally, conventional repair techniques (e.g., redundant row, column, and error correction code (ECC)) fail to increase the single DRAM wafer yield to a desired level.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

A three-dimensional (3D) stacked memory package is described. The 3D stacked memory package includes a base die having an array of processing units (PUs) including at least one spare PU. The 3D stacked memory package also includes memory dies stacked on the base die and having bank tiles, including at least one spare bank tile. The 3D stacked memory package further includes a package substrate supporting the base die. The 3D stacked memory package also includes through substrate vias (TSVs) extending between the memory dies and landing on the base die and having at least one spare TSV per bank tile. The 3D stacked memory package further includes a repair structure configured to reroute a data/control bus to replace a failed bank tile with the spare bank tile, a failed TSV with the at least one spare TSV, and/or a failed PU with the spare PU.

A method of forming a three-dimensional (3D) stacked memory package is described. The method includes stacking a plurality of memory dies on a base die supported by a package substrate. The plurality of memory dies includes a plurality of bank tiles including at least one spare bank tile. The method also includes forming an array of processing units (PUs) on the base die. The array of PUs includes at least one spare PU. The method further includes forming a plurality of through substrate vias (TSVs) extending between the plurality of memory dies and landing on the base die. The plurality of TSVs includes at least one spare TSV per bank tile. The method further includes forming a repair structure configured to reroute a data/control bus to replace one of a failed bank tile with the spare bank tile, a failed through silicon via (TSV) with the at least one spare TSV, and/or a failed PU with the spare PU.

This has outlined, broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for conducting the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the FIGS. is provided for the purpose of illustration and description only and is not intended as a definition of the limits of the present disclosure. Other objects and advantages associated with the aspects disclosed herein will be apparent to those skilled in the art based on the accompanying drawings and detailed description.

### BRIEF DESCRIPTION OF THE DRAWINGS

For a more complete understanding of the present disclosure, reference is now made to the following description taken in conjunction with the accompanying drawings.

FIG. 1 illustrates an example implementation of a system-on-chip (SoC), which includes a repair structure for extreme-bandwidth three-dimensional (3D) stacked dynamic random-access memory (DRAM) including a base die for near-memory computing, in accordance with various aspects of the present disclosure.

FIGS. 2A and 2B illustrate perspective and layout views, respectively, of an extreme-bandwidth 3D stacked memory chip having a base die configured with a repair structure for supporting near-memory computing, according to various aspects of the present disclosure.

FIG. 3 illustrates an overhead view of a repair structure for extreme-bandwidth 3D stacked DRAM including a base die configured for processor-in-memory (PiM) near-memory computing, according to various aspects of the present disclosure.

FIGS. 4A to 4C illustrate a repair structure for extreme-bandwidth 3D stacked DRAM including a base die for near-memory computing, according to various aspects of the present disclosure.

FIGS. 5A to 5F illustrate a process of forming the extreme-bandwidth 3D stacked memory chip, having a base die configured with a repair structure, according to various aspects of the present disclosure.

FIG. 6 is a process flow diagram illustrating a method for forming a repair structure an extreme-bandwidth 3D stacked memory chip, according to various aspects of the present disclosure.

FIG. 7 is a process flow diagram illustrating a method of an example implementation of the method illustrated in FIG. 6, according to various aspects of the present disclosure.

FIG. 8 is a block diagram showing an exemplary wireless communications system in which a configuration of the disclosure may be advantageously employed.

FIG. 9 is a block diagram illustrating a design workstation used for circuit, layout, and logic design of a semiconductor component, such as the vertical bank redundancy in 3D stacked dynamic random-access memory (DRAM) for improved yield disclosed herein.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Disclosed are three-dimensional (3D) stacked memory package and methods for fabricating the same. In an aspect, the 3D stacked memory package includes a base die having an array of processing units (PUs) including at least one spare PU. The 3D stacked memory package also includes memory dies stacked on the base die and having bank tiles, including at least one spare bank tile. The 3D stacked memory package further includes a package substrate supporting the base die. The 3D stacked memory package also includes through substrate vias (TSVs) extending between the memory dies and landing on the base die and having at least one spare TSV per bank tile. The 3D stacked memory package further includes a repair structure configured to reroute a data/control bus to replace a failed bank tile with the spare bank tile, a failed TSV with the at least one spare TSV, and/or a failed PU with the spare PU. In this way, the yield of the 3D stack memory packages can be increased significantly.

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form to avoid obscuring such concepts.

As described herein, the use of the term “and/or” is intended to represent an “inclusive OR,” and the use of the term “or” is intended to represent an “exclusive OR. ” As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches, repeaters, and/or buffers. As described herein, the term “proximate” used throughout this description means “adjacent, very near, next to, or close to. ” As described herein, the term “on” used throughout this description means “directly on” in some configurations, and “indirectly on” in other configurations. It will be understood that the term “layer” includes film and is not construed as indicating a vertical or horizontal thickness unless otherwise stated. As described, the term “substrate” may refer to a substrate of a diced wafer or may refer to a substrate of a wafer that is not diced. Similarly, the terms “chip” and “die” may be used interchangeably.

Memory is a vital component for processing systems, such as wireless communications devices. For example, a cell phone may integrate memory as part of an application processor, such as a system-on-chip (SoC) including a central processing unit (CPU), a graphics processing unit (GPU), and a neural processing unit (NPU). Successful operation of some applications depends on the availability of a high-capacity and low-latency memory solution for scalability of processor workload. A semiconductor memory device solution for providing a high-capacity, low-latency, and high-bandwidth memory is an existing goal for system designers.

Semiconductor memory devices include, for example, static random-access memory (SRAM) and dynamic random-access memory (DRAM). State of the art three-dimensional (3D)-stacked memories composed of high-bandwidth memory (HBM) DRAM provide advantages in performance and power for memory-demanding workloads. Single stacked DRAM yield is a significant factor in these 3D stacked memories. For example, a single DRAM yield of 90% is reduced to a stacked yield of less than 43% in an integration scheme that utilizes low-cost wafer-to-wafer stacking of eight wafers. This stacked yield further drops to 34% whenever the base wafer yield of 80% is combined. Due to this limited yield, DRAM vendors prefer slow and costly die-to-die stacking for implementing HBM solutions. Additionally, conventional repair techniques (e.g., redundant row, column, and error correction code (ECC)) fail to increase the single DRAM wafer yield to a desired level.

In conventional implementations, each DRAM die in a stack of, for example, four DRAM dies, is configured with four (4) channels having dedicated input/outputs (IOs). The channels of the vertical DRAM dies are arranged side-by-side on a base die. Unfortunately, signal routing to IOs and potential memory control circuits on the physical IO module (PHY) involves long wirelengths resulting in a performance and energy/bit penalty. Additionally, significant difficulty is encountered when employing IO and/or bank multiplexing on the base die for performing repairs of a failing bank and/or IO. In particular, the base die is unavailable for performing repairs using, for example, a repair circuit.

In particular, the significant yield loss of 3D stacked DRAM hinders the use of fine-pitch and cheap wafer-to-wafer stacking of DRAMs. For example, fine-pitch stacking (e.g., less than a five-micron pitch) necessitates the wafer-to-wafer stacking of a stacked DRAM wafer to a potential base wafer that contains computing logic. Unfortunately, a low yield of the base wafer significantly reduces the overall yield of stacked DRAMs with the computing logic of the base wafer. Additionally, wide-IO memory necessitates the use of several hundred thousand through substrate vias (TSVs) to enable high-bandwidth applications specified to boost the performance of artificial intelligence (AI) applications that use near-memory computing.

Various aspects of the present disclosure are directed to a novel repair scheme for 3D stacked DRAMs that use a combination of bank repair, TSV repair, and processing unit (PU) repair, which results in more than 95% for the overall yield in high-bandwidth and high-capacity 3D stacked memories that adopt low-cost wafer-to-wafer stacking. Additionally, this novel physical design allows local repair that is close to the spare components (e.g., bank tile, TSV, and processing unit (PU)) without any penalty on the physical design, performance, and energy efficiency of the 3D stacked memories. In some implementations, this repair scheme supports a same layout (e.g., mask) on all DRAM layers without involving a design change. This repair scheme beneficially enables repair after post-stack/package/field-operation of assembly/temperature related failure modes as well as to repair reliability related failures.

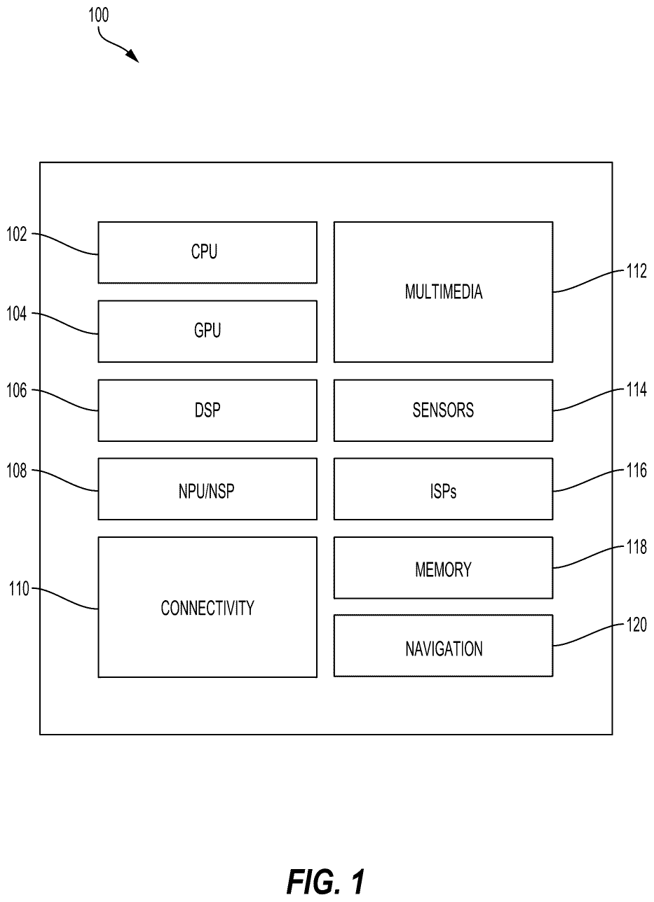

FIG. 1 illustrates an example implementation of a host system-on-chip (SoC) 100, which includes a repair structure for extreme-bandwidth 3D stacked DRAM including a base die for near-memory computing, in accordance with various aspects of the present disclosure. The host SoC 100 includes processing blocks tailored to specific functions, such as a connectivity block 110. The connectivity block 110 may include sixth generation (6G), connectivity fifth generation (5G) new radio (NR) connectivity, fourth generation long term evolution (4G LTE) connectivity, Wi-Fi connectivity, USB connectivity, Bluetooth® connectivity, Secure Digital (SD) connectivity, and the like.

In this configuration, the host SoC 100 includes various processing units that support multi-threaded operation. For the configuration shown in FIG. 1, the host SoC 100 includes a multi-core central processing unit (CPU) 102, a graphics processor unit (GPU) 104, a digital signal processor (DSP) 106, and a neural processor unit (NPU)/neural signal processor (NSP) 108. The host SoC 100 may also include a sensor processor 114, image signal processors (ISPs) 116, a navigation module 120, which may include a global positioning system, and a memory 118. The multi-core CPU 102, the GPU 104, the DSP 106, the NPU/NSP 108, and the multimedia engine 112 support various functions such as video, audio, graphics, gaming, artificial networks, and the like. Each processor core of the multi-core CPU 102 may be a reduced instruction set computing (RISC) machine, RISC-V, an advanced RISC machine (ARM), a microprocessor, or any reduced instruction set computing (RISC) architecture. The NPU/NSP 108 may be based on an ARM instruction set.

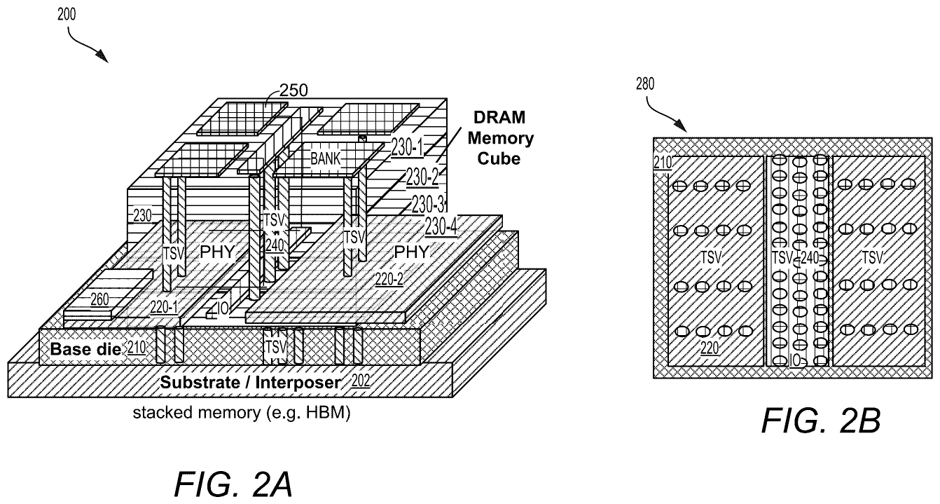

FIGS. 2A and 2B illustrate perspective and layout views, respectively, of an extreme-bandwidth 3D stacked memory chip having a base die configured with a repair structure for supporting near-memory computing, according to various aspects of the present disclosure. As shown in FIG. 2A, an extreme-bandwidth 3D stacked memory chip 200 includes a base die 210 (e.g., a first die) that is supported by a package substrate 202 (e.g., interposer). In various aspects of the present disclosure, the base die 210 supports stacking of memory dies 230 (e.g., dynamic random-access memory (DRAM) dies) on the base die 210. The number of memory dies 230 stacked on the base die 210 varies in different implementations. In this example, four (4) memory dies 230 (230-1, 230-2, 230-3, 230-4) are arranged using a back-to-face stacking of DRAM dies on the base die 210. In another implementation, the base die 210 supports a stack of twelve (12) DRAM dies.

In various aspects of the present disclosure, the memory dies 230 include memory banks (BANK) and an input/output (IO) block that utilize signal through substrate vias (TSVs) 240 extending through the memory dies 230 (e.g., second die) and landing on the base die 210. As shown in FIG. 2A, the signal TSVs 240 provide signal transmission between the memory dies 230 and a first physical IO module (PHY) 220-1 of the base die 210. In this example, a processing unit (PU) 260 (e.g., a neural signal processor (NSP), AI accelerator, GPU) may be implemented on the base die 210 in combination with the PHY 220-1, including a second PHY 220-2 to a system-on-chip (e.g., SoC 100, not shown). Additionally, the high-bandwidth 3D stacked memory chip 200 includes DRAM power TSVs (not shown) between the memory banks and the package substrate 202. In FIG. 2A, only three (3) TSVs 240 are labeled to avoid obscuring the view of the drawing; however, one of skill in the art can readily recognize that there can be more TSVs in the stack of memory dies 230 and/or TSVs 240 at other locations within the stack of memory dies 230.

FIG. 2B illustrates a layout view 280 of the base die 210, further illustrating signal TSV, DRAM power TSV, DRAM signal TSV, and logic power TSV connections, according to various aspects of the present disclosure. Conventional feedthrough power rail (e.g., Vdd-Vss) TSV connections present a considerable number of obstacles to flexibly design blocks on the base die 210 because the feedthrough power rail TSV connections spread across an area defined by a shadow of the stack of memory dies 230. In practice, feedthrough TSVs increase the cost of the base die 210 due to the area consumed by both signal TSVs and power TSVs (e.g., ˜1,000 to 2,000 signal TSVs versus ˜10,000 to 20,000 power TSVs) in the base die 210. Additionally, significant thermal block restrictions on the base die 210 complicate placement of hot compute cores on the base die 210.

As shown in FIGS. 2A and 2B, TSV blocking on the base die 210 forces placement of the IO bus at the center of DRAM die to reduce the TSV obstructions on the base die 210. Additionally, the 3D stacked memory chip 200 includes a central bus 250 propagating signals to the center of the DRAM and back from the center to the PHY 220 located at the edge of base die 210. Unfortunately, the long data routing consumed by the central bus 250 on both the memory dies 230 and base die 210 (e.g., 70-80% of energy/bit penalty) is detrimental to successful operation of the 3D stacked memory chip 200.

In conventional implementations, each of the memory dies 230 in the stack of, for example, four DRAM dies, is configured with four (4) channels having dedicated input/outputs (IOs). The channels of the vertical DRAM dies are arranged side-by-side on the base die 210. Unfortunately, signal routing of the central bus 250 to IOs and potential memory control circuits on the PHY 220 involves long wirelengths resulting in the noted performance and energy per bit penalty. Additionally, significant difficulty is encountered when employing IO and/or bank multiplexing on the base die 210 for performing repairs of a failing bank and/or IO. In particular, the base die 210 is unavailable for performing repairs using, for example, a repair circuit.

Additionally, the significant yield loss of 3D stacked DRAM hinders the use of fine-pitch and cheap wafer-to-wafer stacking of DRAMs. For example, fine-pitch stacking (e.g., less than a five-micron pitch) necessitates the wafer-to-wafer stacking of a stacked DRAM wafer to a potential base wafer that contains computing logic. Unfortunately, a low yield of the base wafer significantly reduces the overall yield of stacked DRAMs with the computing logic of the base wafer. Additionally, wide-IO memories necessitate the use of several hundred thousand TSVs to enable high-bandwidth applications specified to boost the performance of AI applications that use near-memory computing.

To address these and other issues with conventional implementations, it is proposed to provide a repair structure to put redundancy in small blocks, and repeat the redundancies as much as possible. Then the failure rate in each area can become much lower. By repairing local failures, yield can approach almost 100%. In general, the all repair structures—the bank tiles, the processing units, TSVs and memories—can be combined on a same single unit. That is, all components in the same vertical structure can be replaced.

Repair may be performed during tests typically. During the test, e.g., at initial test prior to sending the 3D stacked DRAM to the field for operation, components that have manufacturing issues may be identified. This information—repair code—may be saved in a non-volatile code memory such as fuses, which may also be referred to as fuse bits. For operation, at startup, the repair code may be read from the code memory fuse bits, and the 3D stacked DRAM may be operated with the repair code. As will be demonstrated further below, the repair code may be used to determine the behaviors of the repair multiplexors (MUXes). For example, the repair code may indicate the input selections of the multiplexors. In an aspect, the repair MUXes may be shift-based MUXes. The repair code may be invisible to hardware and/or software during runtime.

Also contemplated is that the repair code may be altered after the implementation of the 3D stacked DRAM. For example, a diagnostic routine may be run to identify further failed components. When diagnosed, the repair code in the code memory may be altered. That is, the repair code may be determined dynamically.

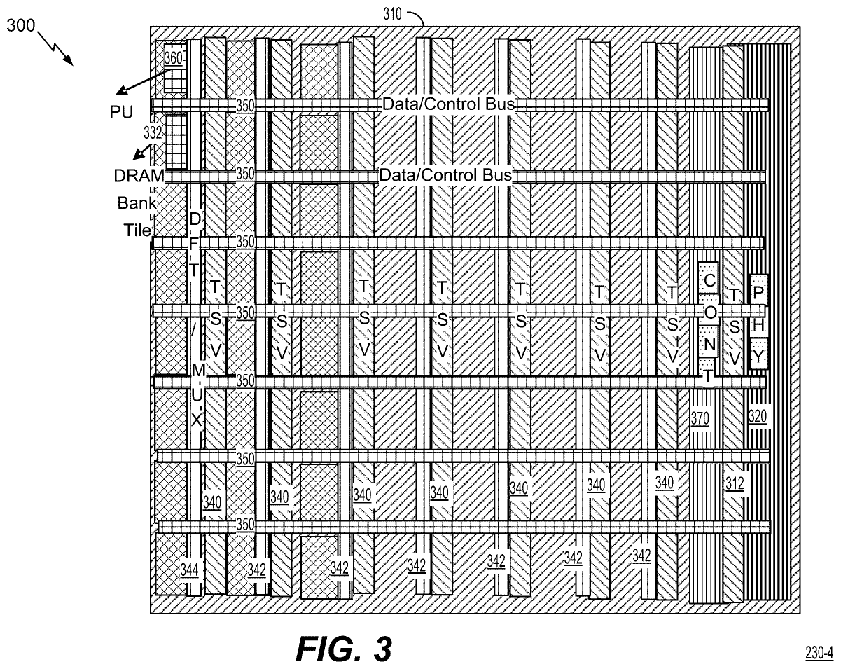

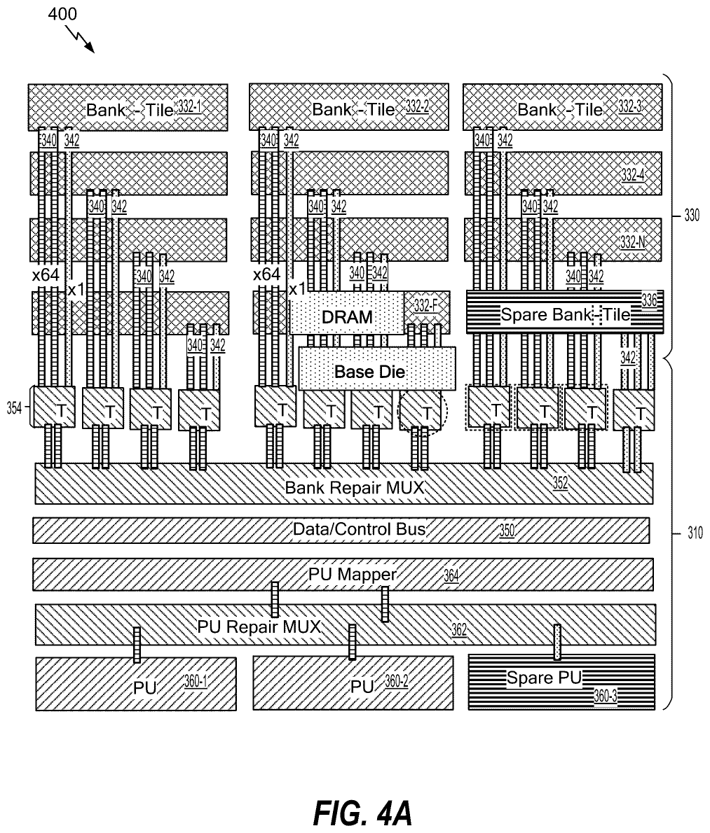

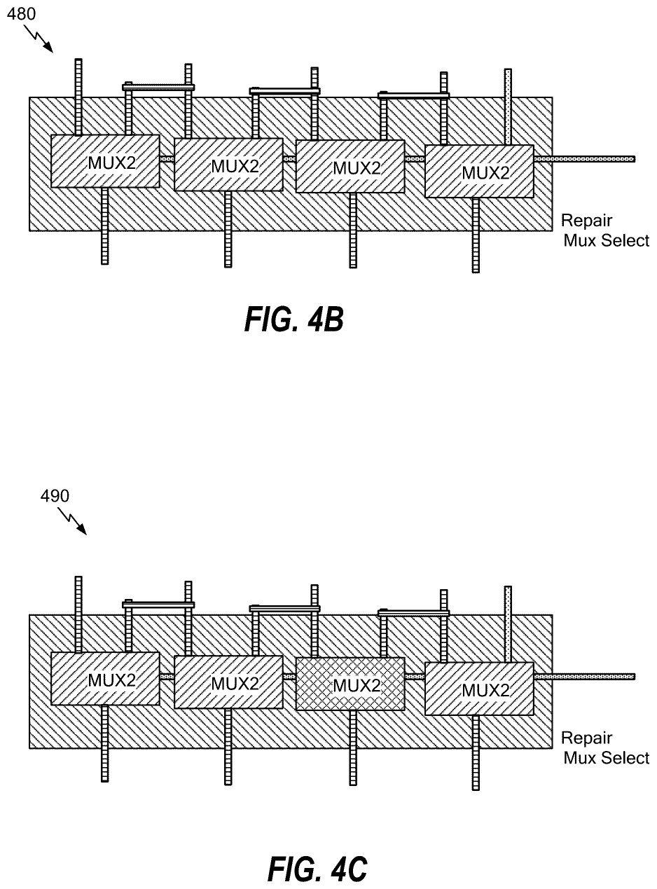

An example of a repair structure for extreme-bandwidth 3D stacked DRAM including a base die for near-memory computing is illustrated, for example, in FIGS. 3 and 4A to 4C. FIG. 3 illustrates an overhead view 300 of a repair structure for extreme-bandwidth 3D stacked DRAM including a base die 310 configured for processor-in-memory (PiM) near-memory computing, according to various aspects of the present disclosure. FIG. 3 illustrates placement of an array of processing units (PUs) 360 on the base die 310. The overhead view 300 further illustrates interconnects of TSV groups 340 and lateral routing of a shared data/control bus 350 and bank tiles 332.

In this example, a spare TSV 342 is provided for each of the TSV groups 340 in case a failed TSV is detected using, for example, a design for test (DFT) multiplexer (MUX) DFT MUX 344. The spare TSV may be defined as a backup TSV that is used only when another TSV is deemed non-functional or failed. Additionally, a controller 370 is provided adjacent to a logic/signal TSV 312 and a PHY 320. In some implementations, the controller 370 is configured as a dataflow controller, including a memory built-in-self-test (MBIST) block (not shown) to select a configuration for repair, and/or test data generation. The overhead view 300 illustrates a novel bank architecture that supplies a repair structure for extreme-bandwidth 3D stacked DRAM including a base die for near-memory computing, as further illustrated in FIGS. 4A to 4C.

FIGS. 4A to 4C illustrate a repair structure 400 for extreme-bandwidth 3D stacked DRAM including a base die for near-memory computing, according to various aspects of the present disclosure. In FIG. 4A the repair structure 400 is described using similar reference numbers to the overhead view 300, as shown in FIG. 3.

As further illustrated in FIG. 4A, the repair structure 400 is implemented to support an extreme-bandwidth 3D stacked memory chip, including a base die 310 that is configured with an array of PUs 360 (360-1, 360-2, 360-3), in which a spare PU 360-3 is provided in case a PU failure (e.g., a failed PU) is detected. The spare PU may be defined as a backup PU that is used only when another PU is deemed non-functional or failed. When a PU failure is detected, a PU repair MUX 362 reroutes the spare PU 360-3 using, for example, a pipeline repair, as further illustrated by repair MUXes 480/490, as shown in FIGS. 4B and 4C. As shown in FIGS. 4B and 4C, the repair MUXes 480/490 are configured as a pipeline of interconnected shift-based multiplexers (MUXes), which utilize short bus lengths for better area performance and energy efficiency. As mentioned above, the repairs for the failures may be recorded as a repair code in a non-volatile code memory (not shown).

In various aspects of the present disclosure, the base die 310 supports stacking of memory dies 330 (e.g., dynamic random-access memory (DRAM) dies) on the base die 310. In this example, bank tiles 332 (e.g., 332-1, 332-2, . . . , 332-N) of the memory dies 330 are shown interconnected with the TSV groups 340 (e.g., x64), each including a spare TSV (e.g., x1). In case of a failed TSV, a TSV MUX 354 (T) is configured to reroute the TSV group 340 to utilize the spare TSV 342 using, for example, a pipeline repair, as further illustrated by repair the MUXes 480/490, shown in FIGS. 4B and 4C. The repair may be written in the code memory as part of the repair code. Note that in an aspect, at least one of the bank tiles 332 may include or correspond to multiple TSVs 340, a spare TSV 342 and a TSV repair MUX 354. Then for the at least one bank tile, the TSV repair MUX 354 may be configured to utilize the spare TSV 342 in place of a failed TSV of the multiple TSVs 340. Thus, the TSVs 340 of each bank tile 332 may be locally repaired.

In case of a failed bank tile 332, a bank repair MUX 352 (B) is configured to reroute the bank tiles 332 to utilize a spare bank tile 336 using, for example, a pipeline repair, as further illustrated by the repair MUXes 480/490, shown in FIGS. 4B and 4C. The spare bank tile may be defined as a backup bank tile that is used only when another bank tile is deemed non-functional or failed. In an aspect, a rerouting of the bank tile 332 may be limited to an immediate neighbor bank tile 332. Thus, when a failed bank tile is detected, outputs of multiple bank tiles 332 may be shifted. For example, in FIG. 4A, assume that the lowest bank tile—bank tile 332-F—in the middle group of bank tiles has failed. The repair MUX 354 associated with the failed bank tile is highlighted with a dashed circle. In this instance, the failed bank tile 332-F is not directly replaced with the spare bank tile 336. The repair mux 354 associated with the failed bank tile 332-F is adjusted to select the inputs of an immediate neighbor bank tile 332-3. That is, in effect, the bank tile 332-3 replaces the failed bank tile 332-F. The repair mux 354 previously receiving the output of the bank tile 323-3 is now adjusted to select the inputs of neighbor bank tile 332-4. That is, in effect, the bank tile 332-4 replaces the bank tile 332-3. Finally, the repair mux 354 previously receiving the output of the bank tile 323-4 is now adjusted to select the inputs of the spare bank tile 446. That is, in effect, the spare bank tile 336 replaces the bank tile 332-4. The selections made by the repair muxes 354 may be written in the repair code of the code memory discussed above. Note that limiting the rerouting to an immediate neighbor bank tile 332 is a form of maintaining local repair. This prevents long signal routing and the penalties associated with conventional repair schemes.

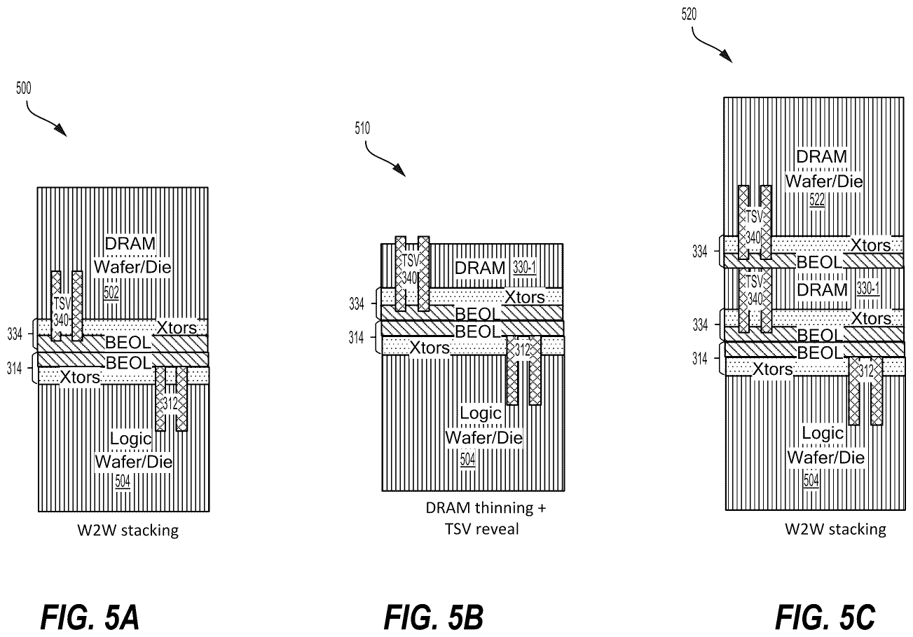

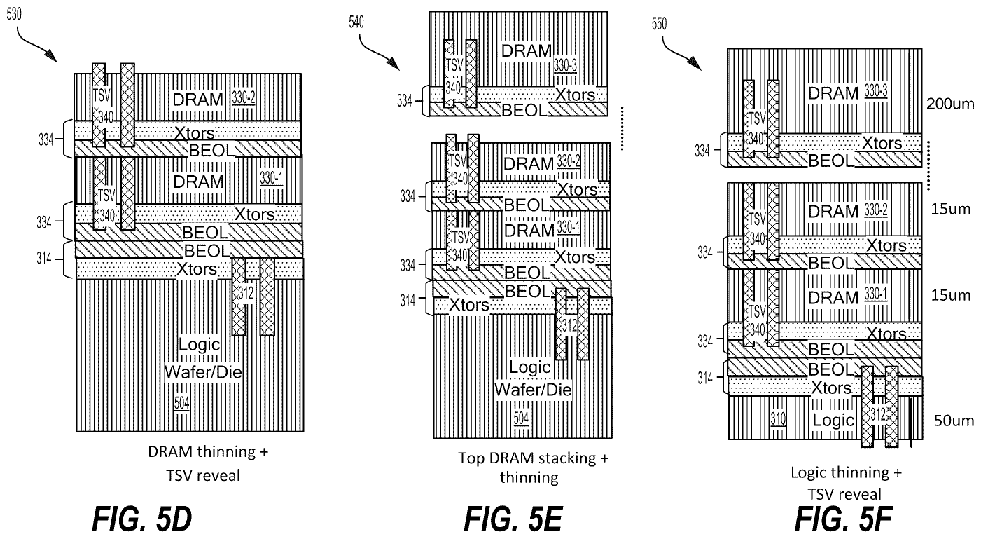

As shown in FIG. 4A, the base die 310 includes the shared data/control bus 350 to route a bank tile 332 through a TSV group 340 to a PU 360 using a PU mapper 364. In operation, the PU mapper 364 is configured to map a PU (e.g., 360) from the array of PUs 360 to a selected bank tile (e.g., 332-2) through a selected one of the TSV groups 340. The repair structure 400 expands the overall coverage of the redundancy in the memory dies 330, which tremendously enhances yield (e.g., 92%) of the 3D stacked memory chip with TSV and PU repair. A process of forming a repair structure in a 3D stacked DRAM for improved yield is illustrated, for example, in FIGS. 5A to 5F.

FIGS. 5A to 5F illustrate a process of forming the extreme-bandwidth 3D stacked memory chip, having a base die configured with the repair structure 400 of FIG. 4A, according to various aspects of the present disclosure. The process of forming the repair structure 400 of FIG. 4A begins in FIG. 5A.

FIG. 5A illustrates a first step 500 in the process of forming the repair structure 400 of FIG. 4A, according to various aspects of the present disclosure. At the first step 500, a DRAM wafer-die 502 is stacked face-down on a base wafer-die 504 (a.k.a. a logic wafer-die) that is face-up according to a wafer-to-wafer (W2W) stacking. In this example, the base wafer-die 504 includes an active layer 314 having a front-end-of-line (FEOL) layer, including transistors (Xtors), and a back-end-of-line (BEOL) layer on the FEOL layer. Similarly, the DRAM wafer-die 502 includes an active layer 334 having an FEOL layer (e.g., Xtors), and a BEOL layer contacted to the BEOL layer of the base wafer-die 504, according to a face-to-face (F2F) stacking. It should be apparent to one of skill in the art that the base wafer-die 504 and/or the DRAM wafer-die 502 can include more than one FEOL layers and/or more than one BEOL layers. However, to simplify and to avoid obscuring the illustration, only one FEOL layer and one BEOL layer are shown in each of the base wafer-die 504 and the DRAM wafer die 502 in the current example.

In this example, a via-middle and redistribution layer (RDL) process forms the logic/signal TSV 312 through the base wafer-die 504 and into the BEOL layer of the active layer 314 of the base wafer-die 504. Similarly, a via-middle and RDL process forms the TSV groups 340 through the DRAM wafer-die 502 and into the BEOL layer of the active layer 334 of the DRAM wafer-die 502.

FIG. 5B illustrates a second step 510 in the process of forming the repair structure 400 of FIG. 4A, according to various aspects of the present disclosure. At the second step 510, the DRAM wafer-die 502 of FIG. 5A is thinned to form a first memory die 330-1, face-down (e.g., active layer 334) on the active layer 314 of the base wafer-die 504. In this example, thinning of the DRAM wafer-die 502 of FIG. 5A reveals the TSV group 340 through a backside of the memory die 330-1.

FIG. 5C illustrates a third step 520 in the process of forming the repair structure 400 of FIG. 4A, according to various aspects of the present disclosure. At the third step 520, a DRAM wafer-die 522 is stacked with wafer-to-wafer (W2W) stacking on the memory die 330-1. In this example, the DRAM wafer-die 522 includes an active layer 334 having an FEOL layer, including transistors (Xtors), and a BEOL layer on an FEOL layer. Additionally, a via-middle and RDL process forms the TSV groups 340 through the DRAM wafer-die 522 and into the BEOL layer of the active layer 334 of the DRAM wafer-die 522.

FIG. 5D illustrates a fourth step 530 in the process of forming the repair structure 400 of FIG. 4A, according to various aspects of the present disclosure. At the fourth step 530, the DRAM wafer-die 522 of FIG. 5C is thinned to form a second memory die 330-2, face-down (e.g., active layer 334) on the first memory die 330-1. In this example, thinning of the DRAM wafer-die 522 of FIG. 5C reveals the TSV group 340 through a backside of the second memory die 330-2.

FIG. 5E illustrates a fifth step 540 in the process of forming the repair structure 400 of FIG. 4A, according to various aspects of the present disclosure. At the fifth step 540, a DRAM wafer-die is stacked with W2W stacking on the second memory die 330-2 and thinned to form a third memory die 330-3, face-down (e.g., active layer 334) on the second memory die 330-2. In this example, the via-last/via-middle and RDL process forms the TSV groups 340 through the third memory die 330-3, the FEOL layer and into the BEOL layer of the active layer 334 of the third memory die 330-3.

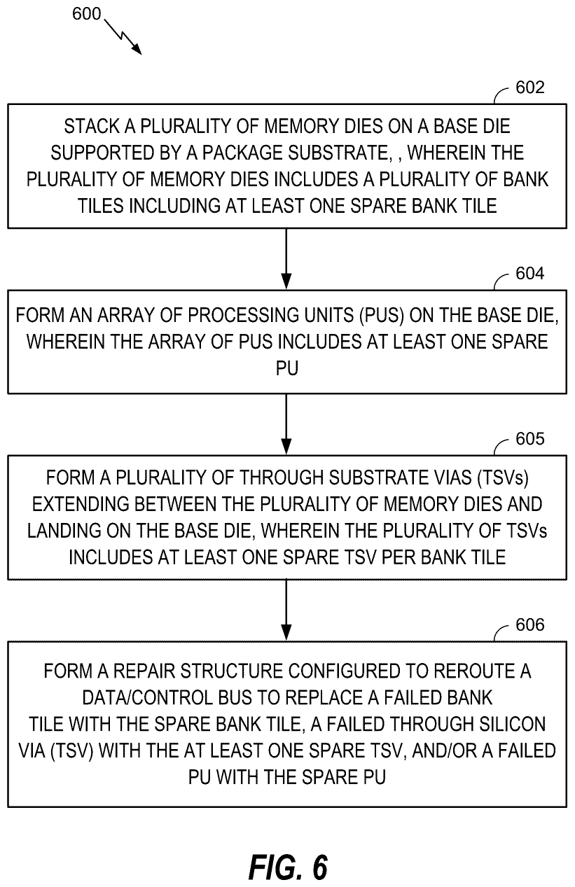

FIG. 5F illustrates a last step 550 in the process of forming the repair structure 400 of FIG. 4A, according to various aspects of the present disclosure. At the last step 550, the base wafer-die 504 of FIG. 5E is thinned to form the base die 310. In this example, thinning of the base wafer-die 504 reveals the logic/signal TSV 312 through the base die 310 and into the BEOL layer of the active layer 314 of the base die 310 at a backside of the base die 310. A process flow for forming a repair structure for an extreme-bandwidth 3D stacked memory chip is illustrated, for example, in FIG. 6.

FIG. 6 is a process flow diagram illustrating a method 600 for forming a repair structure an extreme-bandwidth 3D stacked memory chip, according to various aspects of the present disclosure. The method 600 begins a block 602, in which a plurality of memory dies are stacked on a base die supported by a package substrate. For example, As shown in FIG. 2A, the extreme-bandwidth 3D stacked memory chip 200 includes a base die 210 that is supported by a package substrate 202 (e.g., interposer). The base die 210 supports stacking of memory dies 230 (e.g., dynamic random-access memory (DRAM) dies) on the base die 210.

At block 604, an array of processing units (PUs) are formed on the base die. For example, FIG. 3 illustrates placement of the array of processing units (PUs) 360 on the base die 310. The overhead view 300 further illustrates interconnects of TSV groups 340 and lateral routing of a shared data/control bus 350 and bank tiles 332.

At block 606, a repair structure is formed, which is configured to reroute a data/control bus to replace one of a failed bank tile with a spare bank tile, a failed through silicon via (TSV) with at least one spare TSV, and/or a failed PU with a spare PU. For example, as shown in FIG. 4A, the repair structure 400 is implemented to support an extreme-bandwidth 3D stacked memory chip, including a base die 310 that is configured with an array of PUs 360 (360-1, 360-2, 360-3), in which a spare PU 360-3 is provided in case a PU failure (e.g., a failed PU) is detected. When a PU failure is detected, a PU repair MUX 362 reroutes the spare PU 360-3 using, for example, a pipeline repair, as further illustrated by repair MUXes 480/490, as shown in FIGS. 4B and 4C. As shown in FIGS. 4B and 4C, the repair MUXes 480/490 are configured as a pipeline of interconnected shift-based multiplexers (MUXes), which utilize short bus lengths for better area performance and energy efficiency.

According to various aspects of the present disclosure, a full repair scheme is implemented on a base die with minimal overhead on DRAM dies supported by the base die. In some implementations, the repair scheme provides centralized control of repair of the complete stack of DRAM dies. Additionally, the repair scheme scales the number of TSVs for multiples of a hundred thousand for extreme-bandwidth for high-performance AI processing. Local routing from spare TSVs, banks, and PUs is provided with a minimal energy penalty by enablement of concurrent TSV, bank, and PU repair all in the base die. In some implementations, control/data/repair bus on the base die in rows for dataflow and repair of all units is provided.

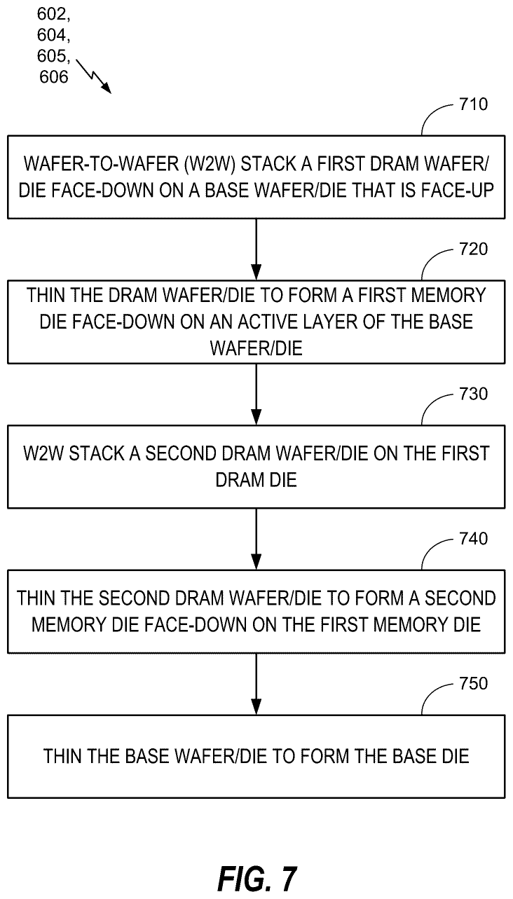

FIG. 7 illustrates a process flow for a particular implementation of the blocks of FIG. 6. At block 710, a first DRAM wafer-die 502 can be wafer-to-wafer (W2W) stacked on a base wafer-die 504 that is face-up. Block 710 may correspond to FIG. 5A.

At block 720, the first DRAM wafer-die 502 thinned to form a first memory die 330-1 face-down on an active layer 314 of the base wafer-die 504. Block 720 may correspond to FIG. 5B.

At block 730, a second DRAM wafer-die 522 may be W2W stacked on the first memory die 330-1. Block 730 may correspond to FIG. 5C.

At block 740, the second DRAM wafer-die 522 may be thinned to form a second memory die 330-2 face-down on the first memory die 330-1. Block 740 may correspond to FIG. 5D. Note that blocks 730 and 740 may be repeated to form further stacked memory dies such as the third memory die 330-3 (e.g., see FIG. 5E).

At block 750, the base wafer-die 504 may be thinned to form the base die 310. Block 750 may correspond to FIG. 6F.

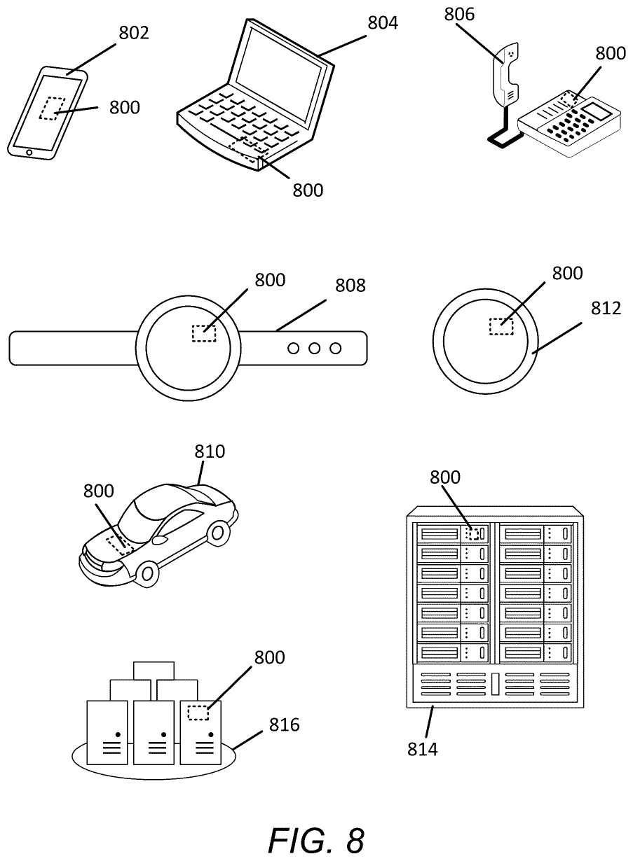

The following should be noted regarding the flow indicated in FIG. 7-8. Unless otherwise indicated, the flow of blocks do not necessarily limit the ordering in which the blocks may be performed. In other words, the blocks may be performed in any order that is logical.

FIG. 8 illustrates various apparatuses (e.g., electronic devices) in which any of the semiconductor devices and/or electronic packages (e.g., die packages) disclosed herein may be integrated, according to aspects of the disclosure. In an aspect, the semiconductor devices and/or electronic packages 800 may be integrated into user equipment (UE), including, by way of example and not limitation, a mobile phone device 802, a laptop computer device 804, a fixed-location terminal device 806, or a wearable device 808.

In other aspects, the semiconductor devices and/or electronic packages 800 may be integrated into electronic devices utilized in automotive applications. Such devices may include, by way of example and not limitation, sensors, controllers, processors, infotainment devices, and the like, which may be installed in a vehicle 810.

In yet other aspects, the semiconductor devices and/or electronic packages 800 may be integrated into a short-range device (SRD) 812. The SRD 812 may comprise, for example, one or more sensors, robotic machines, product code identifiers, electronic pricing and display labels, Internet of Things (IoT) devices, radio frequency identification (RFID) devices, Bluetooth Low Energy® (BLE) devices, or other similar devices.

In further aspects, the semiconductor devices and/or electronic packages 800 may be integrated into a server 814. The server 814 may comprise a computer system configured to provide services, data, or resources to other computers over a network. Such a server 814 may include one or more processors, integrated memory devices, power supplies, or other components mounted in one or more racks.

In yet other aspects, the semiconductor devices and/or electronic packages 800 may be integrated into a data center 816. The data center 816 may comprise a facility configured with one or more servers, storage devices, networking devices, and other supporting devices for storing, processing, and managing data.

The semiconductor devices and/or electronic packages 800 disclosed herein may be fabricated in various package configurations, including, but not limited to, side-by-side (SxS) packages, system-in-package (SiP) configurations, integrated circuit (IC) packages, package-on-package (PoP) devices, or any other suitable packaging configuration, whether disclosed herein or known in the art.

It will be appreciated, based on the teachings of the present disclosure, that the various apparatuses 802, 804, 806, 808, 810, 812, 814, and 816 illustrated in FIG. 8 are merely exemplary. Other apparatuses in which the semiconductor devices and/or electronic packages 800 may be integrated include, without limitation, mobile devices, hand-held personal communication system (PCS) units, portable data units (e.g., personal digital assistants), global positioning system (GPS)-enabled devices, navigation devices, set-top boxes, music players, video players, entertainment units, fixed-location data units, communication devices, smartphones, tablets, computers, wearable devices, servers, routers, memory devices, data centers, automotive electronic devices, Internet of Things (IoT) devices, or any combination thereof.

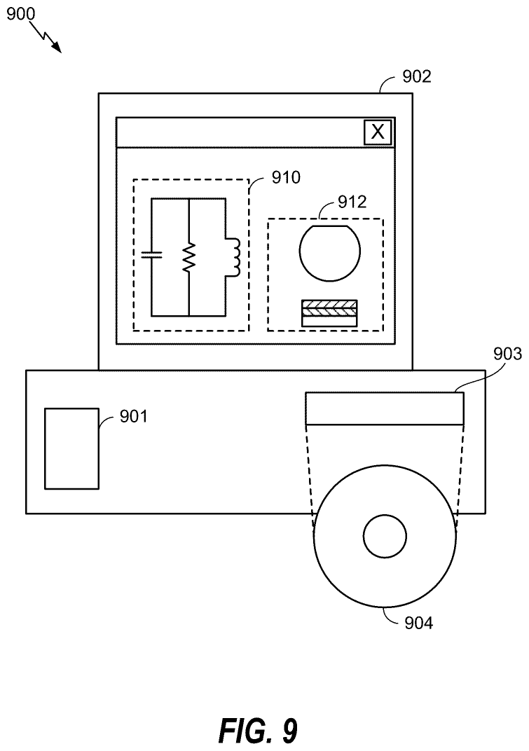

FIG. 9 is a block diagram illustrating a design workstation used for circuit, layout, and logic design of a semiconductor component, such as the vertical bank redundancy in 3D stacked dynamic random-access memory (DRAM) for improved yield disclosed above. A design workstation 900 includes a hard disk 901 containing operating system software, support files, and design software such as Cadence or OrCAD. The design workstation 900 also includes a display 902 to facilitate design of a circuit 910 or an integrated circuit (IC) component 912, such as vertical bank redundancy in 3D stacked DRAM for improved yield. A storage medium 904 is provided for tangibly storing the design of the circuit 910 or the IC component 912 (e.g., the DRAM/SRAM SoC integration). The design of the circuit 910 or the IC component 912 may be stored on the storage medium 904 in a file format such as GDSII or GERBER. The storage medium 904 may be a CD-ROM, DVD, hard disk, flash memory, or other appropriate device. Furthermore, the design workstation 900 includes a drive apparatus 903 for accepting input from or writing output to the storage medium 904.

Data recorded on the storage medium 904 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 904 facilitates the design of the circuit 910 or the IC component 912 by decreasing the number of processes for designing semiconductor wafers.

Implementation examples are described in the following numbered clauses:
1. A three-dimensional (3D) stacked memory package, comprising:
a base die having an array of processing units (PUs) including at least one spare PU;
a plurality of memory dies stacked on the base die and having a plurality of bank tiles, including at least one spare bank tile;
a package substrate supporting the base die;
a plurality of through substrate vias (TSVs) extending between the plurality of memory dies and landing on the base die and having at least one spare TSV per bank tile; and
a repair structure configured to reroute a data/control bus to replace a failed bank tile with the spare bank tile, a failed TSV with the at least one spare TSV, and/or a failed PU with the spare PU.
2. The 3D stacked memory package of clause 1, further comprising a controller configured to control the data/control bus to replace the one of the failed bank tile with the spare bank tile, the failed TSV with the at least one spare TSV, and/or the failed PU with the spare PU.
3. The 3D stacked memory package of any of clauses 1-2, further comprising a design for test (DFT) multiplexer (MUX) to detect the failed TSV, the failed bank tile, and/or the failed PU.
4. The 3D stacked memory package of any of clauses 1-3, further comprising a plurality of TSV repair multiplexers (MUXes) configured to reroute the plurality of TSVs to utilize the spare TSV in place of the failed TSV.
5. The 3D stacked memory package of clause 4,
   wherein there are multiple TSVs, a spare TSV and a TSV repair MUX for at least one bank tile, and
   wherein for the at least one bank tile, the TSV repair MUX is configured to utilize the spare TSV in place of a failed TSV of the multiple TSVs.
6. The 3D stacked memory package of any of clauses 1-5, further comprising a plurality of bank tile repair multiplexers (MUXes) configured to reroute the plurality of bank tiles to utilize the spare bank tile in place of the failed bank tile.
7. The 3D stacked memory package of clause 6, wherein, for each bank tile, a rerouting of the bank tile limited to an immediate neighbor bank tile.
8. The 3D stacked memory package of any of clauses 1-7, further comprising a plurality of PU repair multiplexers (MUXes) configured to reroute the array of PUs to utilize the spare PU in place of the failed PU.
9. The 3D stacked memory package of any of clauses 1-8, further comprising a PU mapper configured to map a PU from the array of PUs to a selected bank tile through a selected TSV group of the plurality of TSV.
10. The 3D stacked memory package of any of clauses 1-9, wherein the repair structure comprises a pipeline of interconnected shift-based multiplexers (MUXes).
11. The 3D stacked memory package of clause 10, further comprising:
   a code memory configured to store a repair code indicating input selections of the shift-based multiplexers (MUXes).
12. The 3D stacked memory package of any of clauses 1-11, wherein a memory die of the plurality of memory dies is stacked face-to-face (F2F) with the base die.
13. The 3D stacked memory package of any of clauses 1-12, further comprising:
   a plurality of signal TSVs extending through the base die; and
   a physical IO module (PHY) coupled to the signal TSVs.
14. The 3D stacked memory package of any of clauses 1-13, wherein the 3D stacked memory package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, a data center, a memory device, and a device in an automotive vehicle.
15. a Method of Forming a Three-dimensional (3d) Stacked Memory Package, the method comprising:
   stacking a plurality of memory dies on a base die supported by a package substrate, wherein the plurality of memory dies includes a plurality of bank tiles including at least one spare bank tile;
   forming an array of processing units (PUs) on the base die, wherein the array of PUs includes at least one spare PU;
   forming a plurality of through substrate vias (TSVs) extending between the plurality of memory dies and landing on the base die, wherein the plurality of TSVs includes at least one spare TSV per bank tile; and
   forming a repair structure configured to reroute a data/control bus to replace a failed bank tile with the spare bank tile, a failed through silicon via (TSV) with the at least one spare TSV, and/or a failed PU with the spare PU.
16. The method of clause 15, further comprising forming a controller configured to control the data/control bus to replace the one of the failed bank tile with the spare bank tile, the failed TSV with the at least one spare TSV, and/or the failed PU with the spare PU.
17. The method of any of clauses 15-16, further comprising forming a design for test (DFT) multiplexer (MUX) to detect the failed TSV, the failed bank tile, and/or the failed PU.
18. The method of any of clauses 15-17, further comprising forming a plurality of TSV repair multiplexers (MUXes) configured to reroute the plurality of TSVs to utilize the spare TSV in place of the failed TSV.
19. The method of clause 18,
   wherein there are multiple TSVs, a spare TSV and a TSV repair MUX for at least one bank tile, and
   wherein for the at least one bank tile, the TSV repair MUX is configured to utilize the spare TSV in place of a failed TSV of the multiple TSVs.
20. The method of any of clauses 15-19, further comprising forming a plurality of bank tile repair multiplexers (MUXes) configured to reroute a plurality of bank tiles to utilize the spare bank tile in place of the failed bank tile.
21. The method of clause 20, wherein, for each bank tile, a rerouting of the bank tile limited to an immediate neighbor bank tile.
22. The method of any of clauses 15-21, further comprising forming a plurality of PU repair multiplexers (MUXes) configured to reroute the array of PUs to utilize the spare PU in place of the failed PU.
23. The method of any of clauses 15-22, further comprising forming a PU mapper configured to map a PU from the array of PUs to a selected bank tile through a selected TSV group of the plurality of TSV.
24. The method of any of clauses 15-23, wherein the repair structure comprises a pipeline of interconnected shift-based multiplexers (MUXes).
25. The method of clause 24, wherein the repair structure further comprises a code memory configured to store a repair code indicating input selections of the shift-based multiplexers (MUXes).
26. The method of any of clauses 15-25, wherein a memory die (330) of the plurality of memory dies (330) is stacked face-to-face (F2F) with the base die (310).
27. The method of any of clauses 15-26, further comprising: forming a plurality of signal TSVs extending through the base die; and forming a physical IO module (PHY) coupled to the signal TSVs.
28. The method of any of clauses 15-27, wherein forming the stacking the plurality of memory dies, forming the array of processing units (PUs) on the base die, forming the plurality of TSVs, and forming the repair structure comprise:
   wafer-to-wafer (W2W) stacking a first DRAM wafer-die face-down on a base wafer-die that is face-up;
   thinning the first DRAM wafer-die to form a first memory die face-down on the active layer of the base wafer-die;
   W2W stacking a second DRAM wafer-die on the first memory die;
   thinning the second DRAM wafer-die form a second memory die face-down on the first memory die; and
   thinning the base wafer-die to form the base die.

For a firmware and/or software implementation, the methodologies may be implemented with modules (e.g., procedures, functions, etc.) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer. Disk and disc, as used herein, include compact disc (CD), laser disc, optical disc, digital versatile disc (DVD), floppy disk and Blu-ray® disc, where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communications apparatus. For example, a communications apparatus may include a transceiver having signals indicative of instructions and data. The instructions and data are configured to cause one or more processors to implement the functions outlined in the claims.

Although the present disclosure and its advantages have been described in detail, various changes, substitutions, and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above, and below may refer to sides of a substrate or electronic device. Moreover, the scope of the present application is not intended to be limited to the configurations of the process, machine, manufacture, composition of matter, means, methods, and steps described in the specification. As one of ordinary skill in the art will readily appreciate from the disclosure, processes, machines, manufacture, compositions of matter, means, methods, or steps, presently existing or later to be developed that perform the same function or achieve the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the application and design constraints imposed on the overall system. Skilled artisans may implement the described functionality in varying ways for each application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA), or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. A three-dimensional (3D) stacked memory package, comprising:
a base die having an array of processing units (PUs) including at least one spare PU;
a plurality of memory dies stacked on the base die and having a plurality of bank tiles, including at least one spare bank tile;
a package substrate supporting the base die;
a plurality of through substrate vias (TSVs) extending between the plurality of memory dies and landing on the base die and having at least one spare TSV per bank tile; and
a repair structure configured to reroute a data/control bus to replace a failed bank tile with the spare bank tile, a failed TSV with the at least one spare TSV, and/or a failed PU with the spare PU.

2. The 3D stacked memory package of claim 1, further comprising a controller configured to control the data/control bus to replace the one of the failed bank tile with the spare bank tile, the failed TSV with the at least one spare TSV, and/or the failed PU with the spare PU.

3. The 3D stacked memory package of claim 1, further comprising a design for test (DFT) multiplexer (MUX) to detect the failed TSV, the failed bank tile, and/or the failed PU.

4. The 3D stacked memory package of claim 1, further comprising a plurality of TSV repair multiplexers (MUXes) configured to reroute the plurality of TSVs to utilize the spare TSV in place of the failed TSV.

5. The 3D stacked memory package of claim 4,
wherein there are multiple TSVs, a spare TSV and a TSV repair MUX for at least one bank tile, and
wherein for the at least one bank tile, the TSV repair MUX is configured to utilize the spare TSV in place of a failed TSV of the multiple TSVs.

6. The 3D stacked memory package of claim 1, further comprising a plurality of bank tile repair multiplexers (MUXes) configured to reroute the plurality of bank tiles to utilize the spare bank tile in place of the failed bank tile.

7. The 3D stacked memory package of claim 6, wherein, for each bank tile, a rerouting of the bank tile limited to an immediate neighbor bank tile.

8. The 3D stacked memory package of claim 1, further comprising a plurality of PU repair multiplexers (MUXes) configured to reroute the array of PUs to utilize the spare PU in place of the failed PU.

9. The 3D stacked memory package of claim 1, further comprising a PU mapper configured to map a PU from the array of PUs to a selected bank tile through a selected TSV group of the plurality of TSV.

10. The 3D stacked memory package of claim 1, wherein the repair structure comprises a pipeline of interconnected shift-based multiplexers (MUXes).

11. The 3D stacked memory package of claim 10, further comprising:
a code memory configured to store a repair code indicating input selections of the shift-based multiplexers (MUXes).

12. The 3D stacked memory package of claim 1, wherein a memory die of the plurality of memory dies is stacked face-to-face (F2F) with the base die.

13. The 3D stacked memory package of claim 1, further comprising:
a plurality of signal TSVs extending through the base die; and
a physical IO module (PHY) coupled to the signal TSVs.

14. The 3D stacked memory package of claim 1, wherein the 3D stacked memory package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, a data center, a memory device, and a device in an automotive vehicle.

15. A method of forming a three-dimensional (3D) stacked memory package, the method comprising:
stacking a plurality of memory dies on a base die supported by a package substrate, wherein the plurality of memory dies includes a plurality of bank tiles including at least one spare bank tile;
forming an array of processing units (PUs) on the base die, wherein the array of PUs includes at least one spare PU;
forming a plurality of through substrate vias (TSVs) extending between the plurality of memory dies and landing on the base die, wherein the plurality of TSVs includes at least one spare TSV per bank tile; and
forming a repair structure configured to reroute a data/control bus to replace a failed bank tile with the spare bank tile, a failed through silicon via (TSV) with the at least one spare TSV, and/or a failed PU with the spare PU.

16. The method of claim 15, further comprising forming a controller configured to control the data/control bus to replace the one of the failed bank tile with the spare bank tile, the failed TSV with the at least one spare TSV, and/or the failed PU with the spare PU.

17. The method of claim 15, further comprising forming a design for test (DFT) multiplexer (MUX) to detect the failed TSV, the failed bank tile, and/or the failed PU.

18. The method of claim 15, further comprising:
forming a plurality of TSV repair multiplexers (MUXes) configured to reroute the plurality of TSVs to utilize the spare TSV in place of the failed TSV;
forming a plurality of bank tile repair multiplexers (MUXes) (352) configured to reroute a plurality of bank tiles to utilize the spare bank tile in place of the failed bank tile; and
forming a plurality of PU repair multiplexers (MUXes) (362) configured to reroute the array of PUs to utilize the spare PU in place of the failed PU,
wherein there are multiple TSVs, a spare TSV and a TSV repair MUX for at least one bank tile, and
wherein for the at least one bank tile, the TSV repair MUX is configured to utilize the spare TSV in place of a failed TSV of the multiple TSVs, and
wherein, for each bank tile, a rerouting of the bank tile limited to an immediate neighbor bank tile.

19. The method of claim 15, wherein the repair structure comprises a pipeline of interconnected shift-based multiplexers (MUXes), the method further comprising forming a code memory configured to store a repair code indicating input selections of the shift-based multiplexers (MUXes).

20. The method of claim 15, wherein forming the stacking the plurality of memory dies, forming the array of processing units (PUs) on the base die, forming the plurality of TSVs, and forming the repair structure comprise:
wafer-to-wafer (W2W) stacking a first DRAM wafer-die face-down on a base wafer-die that is face-up;
thinning the first DRAM wafer-die to form a first memory die face-down on the active layer of the base wafer-die;
W2W stacking a second DRAM wafer-die on the first memory die;
thinning the second DRAM wafer-die form a second memory die face-down on the first memory die; and
thinning the base wafer-die to form the base die.
